(19) United States
(12) Patent Application Publication
(10) Pub. No.: US 2025/0346492 A1
(43) Pub. Date: Nov. 13, 2025

(54) PHOTOCATALYTIC CO2 REDUCTION WITH CO-CATALYST DECORATED NANOSTRUCTURES

(71) Applicants: Yiqing Chen, Ann Arbor, MI (US); Jun Song, Ann Arbor, MI (US); Roksana Rashid, Ann Arbor, MI (US); The Regents of the University of Michigan, Ann Arbor, MI (US)

(72) Inventors: Zetian Mi, Ann Arbor, MI (US); Baowen Zhou, Shanghai (CN); Yiqing Chen, Montreal (CA); Jun Song, Montreal (CA); Roksana Rashid, Waterloo (CA)

(21) Appl. No.: 18/872,689

(22) PCT Filed: Jun. 6, 2023
(86) PCT No.: PCT/US2023/024569

§ 371 Date: Dec. 6, 2024

Related U.S. Application Data
(60) Provisional application No. 63/349,406, filed on Jun. 6, 2022.

(51) Int. Cl. C01B 32/40; B01J 19/12; B01J 23/26; B01J 23/52; B01J 27/24; B01J 35/33; B01J 35/39; B01J 35/45; B01J 37/02; B01J 37/34; C01B 3/04; C23C 14/18; C23C 14/30; C23C 18/14; C30B 23/04; C30B 29/40; C30B 29/60

(52) U.S. Cl. CPC C01B 32/40; B01J 19/127; B01J 23/26; B01J 23/52; B01J 27/24; B01J 35/33; B01J 35/39; B01J 35/45; B01J 37/0228; B01J 37/0244; B01J 37/342; C01B 3/045; C23C 14/18; C23C 14/30; C23C 18/143; C30B 23/04; C30B 29/403; C30B 29/406; C30B 29/60; B01J 2219/00045; B01J 2219/0883; B01J 2219/0884; B01J 2219/0892; B01J 2219/1203

(57) ABSTRACT

A photocatalytic device includes a substrate and an array of conductive projections supported by the substrate and extending outward from the substrate. Each conductive projection of the array of conductive projections has a semiconductor composition configured for charge carrier generation in response to solar radiation. Each conductive projection of the array of conductive projections is decorated with a co-catalyst arrangement. The co-catalyst arrangement includes gold and an oxide material.

### CROSS-REFERENCE TO RELATED APPLICATION

This application claims the benefit of U.S. provisional application entitled “Photocatalytic CO₂ Reduction With Co-Catalyst-Decorated Nanostructures,” filed Jun. 6, 2022, and assigned Ser. No. 63/349,406, the entire disclosure of which is hereby expressly incorporated by reference.

### BACKGROUND OF THE DISCLOSURE

### Field of the Disclosure

The disclosure relates generally to photocatalytic reduction of carbon dioxide (CO₂).

### Brief Description of Related Technology

Syngas, the mixture of CO and H₂, is one of the most useful feedstocks in the chemical industry for producing a huge number of synthetic chemicals and fuels. Over the past century, syngas has mainly been obtained from the fossil fuels reforming with extensive carbon emissions, thus tremendously contributing to the rising concentration of atmospheric carbon dioxide (CO₂).

In contrast, solar-powered CO₂ reduction with H₂O is useful both for renewable CO/H₂ synthesis, as well as for capturing and storing anthropogenic carbon dioxide. However, the direct synthesis of syngas from CO₂ and H₂O is via photocatalysis has remained challenging due to ineffective photon harvesting and severe electron-hole recombination. Due to the stable nature of CO₂ and complex reaction networks, it is extremely difficult to achieve overall CO₂ reduction coupled with H₂O is splitting with tunable CO/H₂ ratios for meeting the practical requirements of various downstream products. Low cost, scalable, high efficiency production of green syngas from solar energy has thus yet to be achieved.

Compared to high-order products, e.g., CH₃OH, CH₄ and C₂₊ compounds, syngas is readily produced via a straightforward 2 H⁺/e⁻ coupled process from both thermodynamic and kinetic points of view, thus promising a technologically and economically viable route for CO₂ fixation. Over the past decades, a broad range of semiconductors have been explored and coupled with various biocatalysts, heterogeneous catalysts, and molecular complexes, for photocatalytic reduction of CO₂. Unfortunately, the reported photocatalysts suffered from one or more deficiencies, including inferior syngas activity, a non-tunable H₂/CO ratio, and low solar-to-syngas energy efficiency. Expensive sacrificial agents, e.g. triethanolamine, were generally required to consume photoexcited holes to close the reaction, and oxygen was not released from water splitting.

Among a variety of materials, Au has been used to catalyze the CO₂ reduction reaction to CO because of its weak interaction with *CO. However, the applicant is not aware of any success in photocatalytic CO₂ reduction for syngas synthesis catalyzed by gold.

Ga(In)N is a III-nitride semiconductor material with an energy bandgap that allows for a broad absorption range of ultra-violet, visible, and near-infrared light without compromising the redox potentials of the CO₂ reduction reaction. Using molecular beam epitaxy technology, the surface properties of III-nitrides have been configured to be N-rich for protection against photo-corrosion and oxidation. With these optical, electronic, and structural properties, Ga (In) N has been used as a semiconductor platform for applied bias-free artificial photosynthesis. For instance, attempts to implement the CO₂ reduction reaction using III-nitrides have been made. Please see AlOtaibi et al., “Wafer-level artificial photosynthesis for CO₂ reduction into CH₄ and CO using GaN nanowires,” ACS Catal. 5,5342-5348 (2015), as well as AlOtaibi et al., “Photochemical carbon dioxide reduction on Mg-Doped Ga(In)N nanowire arrays under visible light irradiation,” ACS Energy Lett. 1, 246-252 (2016).

### SUMMARY OF THE DISCLOSURE

In accordance with one aspect of the disclosure, a photocatalytic device includes a substrate, and an array of conductive projections supported by the substrate and extending outward from the substrate, each conductive projection of the array of conductive projections has a semiconductor composition configured for charge carrier generation in response to solar radiation. Each conductive projection of the array of conductive projections is decorated with a co-catalyst arrangement, the co-catalyst arrangement including gold and an oxide material.

In accordance with another aspect of the disclosure, a method of fabricating a photocatalytic device includes providing a substrate having a surface, forming an array of conductive projections on the substrate such that each conductive projection of the array of conductive projections extends outward from the substrate, each conductive projection of the array of conductive projections having a semiconductor composition configured for charge carrier generation in response to solar radiation, and decorating each conductive projection of the array of conductive projections with a co-catalyst arrangement. Decorating each conductive projection includes depositing gold nanoparticles on each conductive projection and, after depositing the gold nanoparticles, depositing an oxide material to dispose the co-catalyst arrangement in a core-shell configuration.

In accordance with yet another aspect of the disclosure, a method of fabricating a photocatalytic device includes providing a substrate, forming an array of conductive projections on the substrate such that each conductive projection of the array of conductive projections extends outward from the substrate, each conductive projection of the array of conductive projections having a semiconductor composition configured for charge carrier generation in response to solar radiation, and decorating each conductive projection of the array of conductive projections with a co-catalyst arrangement. Decorating each conductive projection includes depositing metallic nanoparticles on each conductive projection using a vapor deposition procedure and, after depositing the metallic nanoparticles, implementing a further deposition procedure to deposit an oxide material to form a core-shell configuration of the co-catalyst arrangement.

In accordance with still another aspect of the disclosure, a catalytic device includes a substrate and a co-catalyst arrangement supported by the substrate, the co-catalyst arrangement including a metallic material and an oxide material. The co-catalyst arrangement is disposed in a core-shell configuration. The metallic material is disposed as a core of the core-shell configuration. The oxide material is disposed as a shell about the core.

In accordance with still another aspect of the disclosure, a method of fabricating a catalytic device includes providing a substrate and forming a plurality of co-catalyst arrangements supported by the substrate, each co-catalyst arrangement of the plurality of co-catalyst arrangements being disposed in a core-shell configuration. Forming the plurality of co-catalyst arrangements includes implementing a vapor deposition procedure to form a core of the core-shell configuration and, after implementing the vapor deposition procedure, implementing a further deposition procedure to form a shell of the core-shell configuration.

In connection with any one of the aforementioned aspects, the devices and/or methods described herein may alternatively or additionally include or involve any combination of one or more of the following aspects or features. The co-catalyst arrangement is disposed in a core-shell configuration with a gold core. The co-catalyst arrangement has a gold-to-oxide material ratio by weight that falls within a range from about 1.2:3.7 to about 1:9.5. The semiconductor composition includes a III-nitride semiconductor material. The III-nitride semiconductor material is doped with magnesium. The III-nitride semiconductor material is InGaN. Each conductive projection of the array of conductive projections includes a nanowire. The oxide material includes chromium oxide. The co-catalyst arrangement is uniformly distributed across the array of conductive projections. Each conductive projection of the array of conductive projections includes a layered arrangement of semiconductor materials. The layered arrangement of semiconductor materials establishes a multiple band structure. The co-catalyst arrangement is configured for catalysis of carbon dioxide (CO₂) reduction. A method of using the photocatalytic device as disclosed herein, the method including illuminating the photocatalytic device with incident solar radiation, and capturing a product of the CO₂ reduction. The co-catalyst arrangement is configured such that the product includes syngas. The photocatalytic device is illuminated without application of a bias voltage to the photocatalytic device. The method further including disposing the photocatalytic device in a container, and supplying water or water vapor and CO₂ to the container. Illuminating the photocatalytic device is implemented while the container is free of a sacrificial agent for the CO₂ reduction. Decorating each conductive projection includes configuring a deposition procedure to establish a gold-to-oxide material ratio by weight that falls within a range from about 1.2:3.7 to about 1:9.5. Depositing the oxide material includes implementing a photo-deposition procedure. Depositing the gold nanoparticles includes implementing an e-beam evaporation procedure to deposit the gold nanoparticles. Forming the array of conductive projections includes implementing a molecular beam epitaxy (MBE) procedure to grow a stack of a plurality of III-nitride semiconductor segments. Each III-nitride semiconductor segment of the plurality of III-nitride semiconductor segments has a respective bandgap for charge carrier generation in response to solar radiation. The stack includes a plurality of GaN segments, each GaN segment of the plurality of GaN segments being disposed between a respective adjacent pair of III-nitride semiconductor segments of the plurality of III-nitride semiconductor segments. The metallic nanoparticles include gold. The vapor deposition procedure includes e-beam evaporation. The further deposition procedure includes a photo-deposition procedure. The metallic material is gold. The vapor deposition procedure includes e-beam evaporation. The further deposition procedure includes a photo-deposition procedure. The further deposition procedure includes an electro-deposition procedure.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a schematic view of a photocatalytic device having a co-catalyst arrangement for reduction of carbon dioxide (CO₂) in accordance with one example.

FIG. 2 is a flow diagram of a method of fabricating a photocatalytic device having a co-catalyst arrangement for reduction of carbon dioxide (CO₂) in accordance with one example.

FIG. 3 depicts a schematic view of a Mg-doped InGaN/GaN nanowire of a photocatalytic device in accordance with one example, along with a scanning electron microscopy (SEM) image of InGaN/GaN nanowires, a graphical plot of a photoluminescence (PL) spectrum of the InGaN/GaN nanowires, a high-angle annular dark field (HAADF-STEM) image of an InGaN/GaN nanowire, and an energy dispersive X-Ray (EDX) line scan showing the distribution of In, Ga and N along a line in the HAADF-STEM) image.

FIG. 4 depicts a HAADF-STEM image of an InGaN/GaN nanowire decorated with a co-catalyst arrangement in accordance with one example, along with scanning transmission electron microscopy (STEM)-EDX elemental mapping images of Ga, In, N, Au, and Cr with overall mapping, a transmission electron microscopy (TEM) image of the nanowire, with an inset of a high resolution TEM image of a core/shell configuration on the nanowire surface, and high-resolution XPS images of Au 4f and Cr 2p of the decorated InGaN/GaN nanowire.

FIG. 5 depicts a schematic view of a CO2 reduction reaction with a InGaN/GaN nanowire decorated with a co-catalyst arrangement in accordance with one example, along with graphical plots of output gas evolution with various co-catalysts and with various co-catalyst ratios, a graphical plot of STS efficiency as a function of co-catalyst ratio, and a graphical plot of H₂, O₂ and CO evolution, with dashed lines indicating the evacuation of a photoreactor and a restart of the test.

FIG. 6 depicts graphical plots of photocatalytic activity of InGaN/GaN nanowires decorated with a co-catalyst arrangement in accordance with one example, including a gas evolution comparison between AM 1.5 G and a 400 nm filter, and repeated cycles of photocatalytic gas evolution.

FIG. 7 depicts schematic, side views of optimized configurations of CO₂ adsorbed on (a) Au(111), (b) Cr₂O₃(0001), and (c) Au₄/Cr₂O₃, along with calculated free energy diagrams for CO₂ reduction and hydrogen evolution reactions on different substrates (Au, Cr, C, and O).

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Photocatalytic devices having conductive projections decorated with a co-catalyst arrangement for CO₂ reduction are described. The disclosed devices include nanowires, nanostructures, or other conductive projections that include one or more III-nitride semiconductors configured for charge carrier generation in response to solar radiation. For instance, each nanowire, nanostructure, or other conductive projection may include multiple segments with differing alloy concentrations to capture multiple bands of solar wavelengths. Each nanowire, nanostructure, or other conductive projection is decorated with a co-catalyst arrangement configured for the CO₂ reduction reaction. As described below, the co-catalyst arrangement includes a metal (e.g., gold) and an oxide material, which may be disposed in a core-shell configuration. Methods for fabricating such devices are also described.

The disclosed devices are capable of catalyzing the reduction of CO₂ with water in the absence of applied bias and/or sacrificial agents. For instance, triethanolamine or other sacrificial agents are not required to close the reaction. In this way, operation of the devices may only involve water, CO2, and sunlight as inputs. As a result, the production of green syngas and/or other chemicals may be realized.

The III-nitride semiconductor-based projections and co-catalyst arrangement present a useful combination of an effective catalyst and a semiconductor platform for the CO₂ reduction reaction. The III-nitride semiconductor materials are highly efficient in generating charge carriers from solar radiation. The co-catalyst arrangement allows the products of the reduction reaction to be tunable. Thus, the ratio of hydrogen to CO in syngas may be tailored via adjustment of the ratio in the co-catalyst arrangement.

The disclosed devices and systems may include multi-band (e.g., quadruple-band) for artificial photosynthesis and solar fuel conversion with significantly improved performance. For instance, the disclosed devices and systems may include InGaN nanowire arrays to improve the efficiency of the conversion. For example, each nanowire may include layers or segments of different semiconductor compositions, such as In_{0.35}Ga_{0.65}N, In_{0.27}Ga_{0.73}N, In_{0.20}Ga_{0.80}N, and GaN, which present energy bandgaps about 2.1 eV, 2.4 eV, 2.6 eV, and 3.4 eV, respectively. As described herein, such multi-band InGaN and other nanowire arrays are integrated directly on a wafer for enhanced light absorption.

In some cases, the disclosed devices are configured for photochemical syngas synthesis using a core/shell dual co-catalyst (e.g., Au and Cr₂O₃) in coordination with multi-stacked (or multi-band) InGaN/GaN nanowires. This combination allows syngas to be produced solely from CO₂, H₂O, and solar light. The Au and Cr₂O₃ co-catalysts work synergistically to deform the linear CO₂ molecule, thus reducing the energy barrier of the CO₂ reduction reaction. The co-catalyst arrangement also promotes the hydrogen evolution reaction simultaneously. Examples that combine the optoelectronic properties of the multi-stacked InGaN/GaN nanowires with the co-catalyst arrangement have demonstrated both high syngas activity and impressive solar-to-syngas efficiency, as well as broadly tunable CO/H₂ ratios. The capability to tune the output ratio allows the disclosed devices to support a wide range of chemical refinery and other applications.

The configuration of the multi-band nanostructure arrays may vary. In some cases, the arrays include monolithically integrated multiple-band InGaN nanostructures configured to act as photocatalysts. For instance, each nanostructure may include Mg-doped (p-type) In_{0.35}Ga_{0.65}N (E_{g} of about 2.1 eV), In_{0.27}Ga_{0.73}N (E_{g} of about 2.4 eV), In_{0.20}Ga_{0.80}N (E_{g} of about 2.6 eV) and GaN (E_{g} of about 3.4 eV) segments. Each nanostructure may thus be capable of absorbing a wide range of the solar spectra, including, for instance, ultraviolet and visible portions of the solar spectra. Additional, fewer, or alternative segments may be included.

Although described in connection CO₂ reduction into syngas, the disclosed photocatalytic devices and systems may be used in other chemical reaction contexts and applications. For instance, the disclosed photocatalytic devices and systems may be useful in connection with CO₂ reduction to various fuels and other chemicals, and activation of C—H bonds for the production of various chemicals. The photocatalytic devices may also be used in connection with still other reactions not involving CO₂ reduction. such as nitrogen reduction to ammonia.

Although described herein in connection with electrodes having GaN-based nanowire arrays for CO₂ reduction, the disclosed devices are not limited to GaN-based nanowire arrays. A wide variety of other types of nanostructures and other conductive projections may be used. Other III-nitride semiconductors may also be used. Thus, the nature, construction, composition, configuration, characteristics, shape, and other aspects of the conductive projections through which the CO₂ reduction is catalyzed may vary.

Although described herein in connection with photocatalytic devices, one or more aspects of the disclosed devices may be applied to catalyzing other types of reactions. For instance, the disclosed devices may be used to catalyze reactions driven by electrical or thermal energy (either alone or in combination and/or in combination with light). The disclosed devices may accordingly include a co-catalyst arrangement as described herein that are supported by a substrate, in which the co-catalyst arrangement includes a metallic material (e.g., gold) and an oxide material, and in which the co-catalyst arrangement is disposed in a core-shell configuration with the oxide material configured as a shell about the gold.

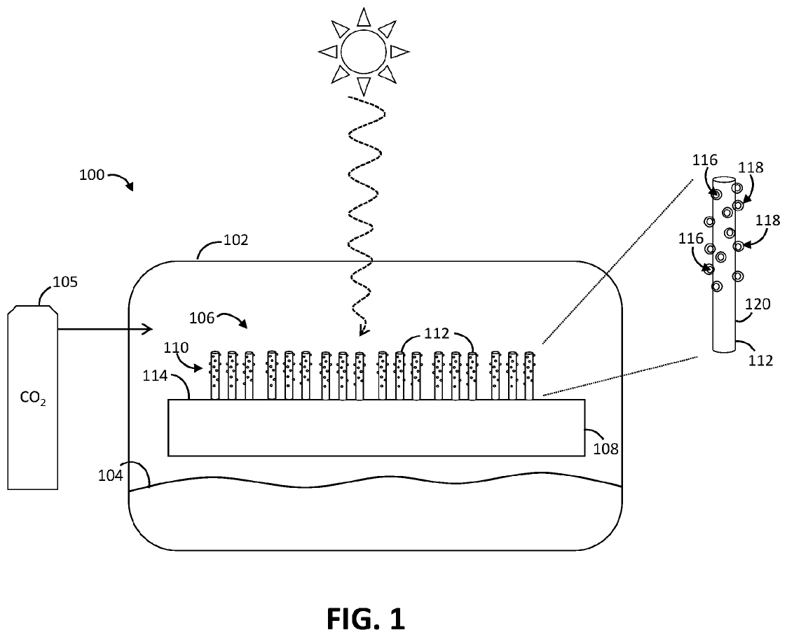

FIG. 1 depicts a photocatalytic system 100 for CO₂ reduction. The CO₂ reduction may include or involve photocatalytic water splitting. Other chemical reactions may also be implemented or supported by the system 100. In this example, the photocatalytic system 100 includes a container 102. In some cases, the container 102 is configured as a sealed reactor, such as a sealed gas-phase reactor. The container 102 may be configured to allow illumination (e.g., solar illumination) of the interior of the container 102. For instance, the container 102 may have a transparent cover, side, cap, or other portion, such as a quartz top. The manner in which the system 100 is illuminated may vary. The size, construction, composition, configuration, and other characteristics of the container 102 may vary. The system 100 may not include a container in other cases.

In the example shown, liquid water 104 is disposed in the container 102. The water 104 may or may not be pure water (e.g., distilled water). The pH of the water 104 may vary accordingly. In some cases, the water 104 evaporates and/or is vaporized prior to operation. Alternatively or additionally, water vapor may be provided to the container directly. In still other cases, all of the water 104 remains in the liquid phase.

The system 100 may include a source 105 of CO₂ coupled to the container 102. The CO₂ source 105 may be integrated to any desired extent with a source of water or water vapor. In some cases, the system 100 receives CO₂ passively and/or without an express source. For example, CO₂ may be supplied in part or whole from the ambient.

As described herein, the system 100 does not include a voltage or other source of electrical energy. Thus, in the example of FIG. 1, the system 100 accordingly implements the CO₂ reduction without the application of a bias voltage to a photocatalytic device of the system 100. In other cases, one or more bias voltages may be applied to one or more electrodes or other components in the system 100.

The system 100 may also be free of sacrificial agents. In the example of FIG. 1, the container 102 is sacrificial agent-free. In other cases, one or more sacrificial agents may be used to promote the CO₂ reduction reaction in the system 100.

The photocatalytic system 100 includes a photocatalytic device 106 disposed in the container 102. The photocatalytic device 106 may or may not be immersed (e.g., partially or completely) in the water 104. In the example of FIG. 1, the photocatalytic device 106 is disposed in the container 102 in a manner to allow the incident light to illuminate the semiconductor device 106. In some cases, the photocatalytic device 106 is configured for CO₂ reduction with water splitting in response to the illumination.

The semiconductor device 106 includes a substrate 108 and an array 110 of conductive projections 112 supported by the substrate 108. In some cases, each conductive projection 112 is or includes a nanowire or other nanostructure. In this example, each conductive structure 112 is or includes a cylindrically shaped nanostructure. The cylindrical shape has a circular cross-sectional shape (e.g., a circular cylinder), as opposed to, for instance, a plate-shaped or sheet-shaped nanostructure. The conductive projections 112 may thus be configured, and/or referred to herein, as nanowires. In this example, the nanowires 112 extend outward from a top or upper surface 114 of the substrate 108. Alternative or additional surfaces of the substrate 108 may support the array 110.

The substrate 108 may be active (e.g., functional) and/or passive (e.g., structural). In one example of the former case, the substrate 108 may be or include a reflective material or layer to direct light back toward the nanowires 112. In one example of the latter case, the substrate 108 may be configured and act solely as a support structure for the nanowires 112. Alternatively or additionally, the substrate 108 may be composed of, or otherwise include, a material suitable for the growth or other deposition of the nanowires 112.

The substrate 108 may include a light absorbing material. In such cases, the light absorbing material is configured to generate charge carriers upon solar or other illumination. The light absorbing material has a bandgap such that incident light generates charge carriers (electron-hole pairs) within the substrate. Some or all of the substrate 108 may be configured for photogeneration of electron-hole pairs.

The substrate 108 may include a semiconductor material. In some cases, the substrate 108 is composed of, or otherwise includes, silicon. For instance, the substrate 108 may be provided as a silicon wafer. The silicon may or may not be doped. The doping arrangement may vary. For example, one or more components of the substrate 108 may be non-doped (intrinsic), or effectively non-doped. The substrate 108 may include alternative or additional layers, including, for instance, support or other structural layers. The composition of the substrate 108 may thus vary. For example, the substrate may be composed of, or otherwise include, metal films, GaAs, GaN, or SiOₓ in other cases.

The substrate 108 may establish a surface, e.g., the surface 114, at which a catalyst arrangement (e.g., a photocatalyst arrangement) of the semiconductor device 106 is provided. The photocatalyst arrangement is provided by the nanowires 112 of the array 110. In some cases, the catalyst arrangement may be a co-catalyst arrangement including a nanowire-nanoparticle architecture, as described herein.

Each nanowire 112 has a semiconductor composition for charge carrier generation in response to solar radiation. In some cases, the semiconductor composition includes one or more III-nitride semiconductor materials, such as gallium nitride (GaN) and/or one or more alloys of indium gallium nitride (InGaN). Further details regarding examples having stacks of GaN/InGaN segments are provided below. Additional or alternative semiconductor materials may be used, including, for instance, indium nitride, indium gallium nitride, aluminum nitride, boron nitride, aluminum oxide, and silicon, gallium phosphide, gallium arsenide, indium phosphide, tantalum nitride, silicon, and other semiconductor materials.

Each nanowire 112 may be or include a columnar, rod-shaped, post-shaped, or other elongated structure. The nanowires 112 may be grown or formed as described in U.S. Pat. No. 8,563,395 (“Method of growing uniform semiconductor nanowires without foreign metal catalyst and devices thereof”), the entire disclosure of which is hereby incorporated by reference. The dimensions (e.g., length, diameter), size, shape, and other characteristics of the nanowires 112 may vary.

The semiconductor composition of each nanowire 112 allows charge carriers to be generated to support the CO₂ reduction reaction and water splitting (i.e., water oxidation reaction of 2H₂O→O₂+4H⁺+4e⁻). Proton diffusion from the water oxidation reaction to the CO₂ reduction reaction may occur across a single one of the nanowires 112. Alternatively or additionally, the proton diffusion may occur between two adjacent nanowires 112 in the array 110. The protons may diffuse through liquid water present between the nanowires 112 and/or through the water 104 or other liquid in which the device 100 is immersed.

Each nanowire 112 extends outward from the surface 114 of the substrate 108. In this example, the surface 114 of the substrate 108 is planar. Alternatively or additionally, the surface 114 of the substrate is nonplanar. In such cases, one or more subsets of the array 110 may be oriented at different angles. Examples of nonplanar substrates include various types of multi-faceted surfaces, such as a pyramidal textured surface. For instance, the pyramids of the surface 114 are square-based pyramids with four sides defined by the <111> crystallographic planes. Further details regarding examples of such nonplanar substrates and corresponding dopant gradients are provided in International Publication No. WO 2021/195484 (“Doping Gradient-Based Photocatalysis,” the entire disclosure of which is hereby incorporated by reference. The manner in, or degree to, which the surface 114 is multi-faceted or otherwise nonplanar may vary. For instance, the surface 114 may have any number of faces oriented at any angle. The pyramids or other shapes along the surface 114 may be uniform or non-uniform.

The nanowires 112 may be configured to generate electron-hole pairs upon illumination. The nanowires 112 may be configured to generate the electron-hole pairs upon absorption of light at certain wavelengths (e.g., solar wavelengths). In some cases, each nanowire 112 may have multiple segments, with each segment being configured to absorb light over a respective range of wavelengths and, thus, improve the efficiency of the photocatalytic water splitting. For instance, each nanowire 112 may include a stacked or layered arrangement of semiconductor materials. Each layer in the arrangement may be configured for absorption of light of solar wavelengths (e.g., infrared, visible, and/or ultraviolet wavelengths).

The layered arrangement of semiconductor materials is used to establish a multi-band structure, such as a quadruple band structure. Each layer or segment of the arrangement may have a different semiconductor composition to establish a different bandgap. For instance, in III-nitride examples, the layers or segments of the arrangement may have different indium and gallium compositions. Examples of layered arrangements configured to provide a multi-band structure are shown and described below.

The layered arrangement of the nanowires 112 may vary from the examples described herein. For example, further details regarding the formation and configuration of multi-band structures, including, for instance, triple-band structures, are provided in U.S. Pat. No. 9,112,085 (“High efficiency broadband semiconductor nanowire devices”) and U.S. Pat. No. 9,240,516 (“High efficiency broadband semiconductor nanowire devices”), the entire disclosures of which are incorporated by reference.

The semiconductor composition of each nanowire 112 may be configured to improve the efficiency of the water splitting and CO₂ reduction reaction in additional ways. For instance, in some cases, the semiconductor composition of each nanowire 112 may include doping to promote charge carrier separation and extraction, as well as to facilitate the establishment of a photochemical diode (e.g., to promote charge carrier separation and extraction). For example, a dopant concentration of the semiconductor composition may vary laterally and/or from layer to layer.

In examples involving III-nitride compositions, the dopant may be or include magnesium. Further details regarding the manner in which magnesium doping promotes charge carrier separation and extraction are set forth in U.S. Pat. No. 10,576,447 (“Methods and systems relating to photochemical water splitting”), the entire disclosure of which is incorporated by reference. Additional or alternative dopant materials may be used, including, for instance, silicon, carbon, zinc, and beryllium, depending on the semiconductor light absorber of choice.

The photocatalytic device 106 further includes a co-catalyst arrangement supported by the array 110 of nanowires 112. As shown in FIG. 1, each nanowire is decorated with a co-catalyst arrangement. The co-catalyst arrangement may include a metal (e.g., gold) and an oxide material as dual catalysts 116, 118. The dual catalysts 116, 118 are distributed or disposed over the array 110 of nanowires 112. Pluralities of each type of the catalyst 116, 118 are disposed on each nanowire 112, as schematically shown in FIG. 1. The dual catalysts 116, 118 are distributed across or along the outer surface(s) of each nanowire 112. In the example of FIG. 1, the catalysts 116, 118 are disposed along sidewalls 120 of the nanowires 112. Alternatively or additionally, the catalysts 116, 118 are disposed along one or more other surfaces of the nanowires 112, such as a top or upper surface.

In some cases, the co-catalyst arrangement may be disposed in a core-shell configuration. As shown in FIG. 1, the catalyst 116 may be surrounded by the catalyst 118. The catalyst 116 is provided or configured as a metal (e.g., gold) core of the core-shell configuration. For instance, the catalyst 116 may be configured as, or otherwise include, a nanoparticle composed of, or otherwise including, gold. The catalyst 118 is provided or configured as a shell of the core-shell configuration. For instance, the catalyst 118 may be configured as, or otherwise include, a shell composed of, or otherwise including, an oxide material. The nanoparticle of the catalyst 116 may or may not be completely enclosed, encompassed, or covered by the shell of the catalyst 118. For instance, the catalyst 116 may be disposed between the catalyst 118 and an outer surface of the nanowire 112.

The nanoparticle catalysts 116 and the shell catalysts 118 are configured to facilitate or promote the CO₂ reduction reaction. The nanoparticles 124 are configured to facilitate or promote the proton reduction reaction. Further details regarding the formation, configuration, functionality, and other characteristics of nanoparticles in conjunction with a nanowire array are set forth herein and/or in one or more of the above-referenced U.S. patents.

In some cases, the shell catalysts 118 are composed of, or otherwise include, chromium oxide (CR₂O₃). However, additional or alternative oxide materials may be used, including, for instance, iridium oxide, copper oxide, and nickel oxide.

In some cases, the nanoparticle catalysts 116 are composed of, or otherwise include, a metal other than gold. For instance, additional or alternative metallic materials may be used, including, for instance, platinum, nickel, palladium, iron, and copper, as well as alloys thereof.

The co-catalyst arrangement may have a gold-to-oxide material ratio by weight configured to tune or establish an output product ratio for the device 100. For instance, the H₂-to-CO ratio may be tuned in this manner. In some cases, the gold-to-oxide material ratio falls within a range from about 1.2:3.7 to about 1:9.5, but other ratios may be used.

The distribution of the dual catalysts 116, 118 may be uniform or non-uniform. For instance, the dual catalysts 116, 118 may thus be distributed uniformly in the sense that each nanowire 112 is decorated with the dual catalysts 116, 118. The specific location of the dual catalysts 116, 118 on each nanowire 112 may be differ from nanowire to nanowire. The schematic arrangement of FIG. 1 is shown for ease in illustration.

The nanowires 112 and the dual catalysts 116, 118 are not shown to scale in the schematic depiction of FIG. 1. The shape of the nanowires 112 and the dual catalysts 116, 118 may also vary from the example shown. Further details regarding the nanowires and co-catalyst arrangement, including the fabrication thereof, are provided below.

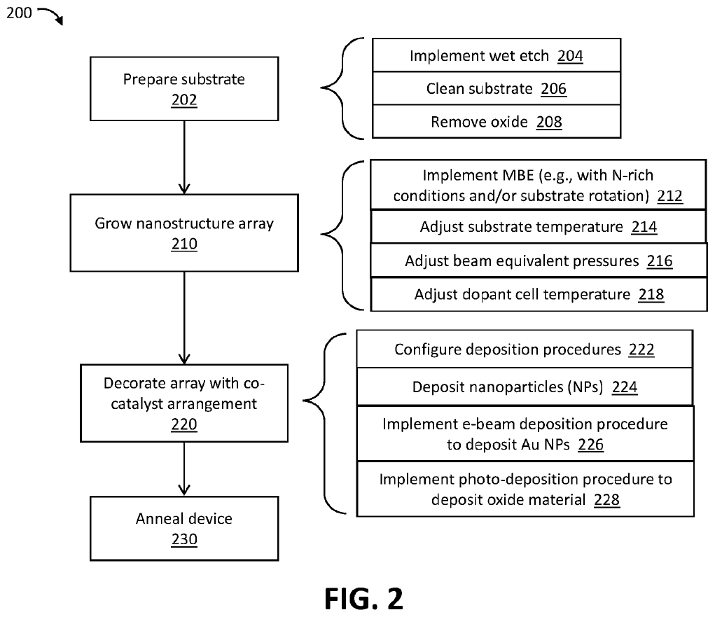

The nanowire and co-catalyst arrangement may be fabricated on a substrate (e.g., a silicon substrate) via nanostructure engineering. In one example, molecular beam epitaxial (MBE) growth of the nanowires is followed by photo-and/or other deposition of the catalysts. Further details regarding example fabrication procedures are provided below, e.g., in connection with FIG. 2.

The nanowires 112 may facilitate the water splitting in alternative or additional ways. For instance, each nanowire 112 may be configured to extract charge carriers (e.g., electrons) generated in the substrate 108 (e.g., as a result of light absorbed by the substrate 108). In such cases, the opposite side of the substrate 108 may be configured for hole extraction. The extraction brings the charge carriers to external sites along the nanowires 112 for use in the reduction of CO₂ and/or other reactions.

FIG. 2 depicts a method 200 of fabricating a photocatalytic device for CO₂ reduction in accordance with one example. The method 200 may be used to manufacture any of the devices described herein or another device. The method 200 may include additional, fewer, or alternative acts. For instance, the method 200 may or may not include one or more acts directed to annealing the device (act 230).

The method 200 may begin with an act 202 in which a substrate is prepared or otherwise provided. The substrate may be or be formed from a silicon wafer. In one example, a 2-inch Si wafer was used, but other (e.g., larger) size wafers may be used. Other semiconductors and substrates may be used.

In some cases, the act 202 includes an act 204 in which a wet or other etch procedure is implemented to define the surface (e.g., nonplanar surface). For example, the etch procedure may be or include a crystallographic etch procedure. In silicon substrate examples, the crystallographic etch procedure may be or otherwise include a KOH etch procedure. In such cases, if the substrate has a <100> orientation, the wet etch procedure establishes that the surface includes a pyramidal textured surface with faces oriented along <111> planes, but additional or alternative facets may be present in some cases.

The act 202 may include fewer, additional, or alternative acts. For instance, in the example of FIG. 1, the act 202 includes an act 206 in which the substrate is cleaned, and an act 208 in which oxide is removed.

In one example, a prime-grade polished silicon wafer is etched in 80° C. KOH solution (e.g., 1.8% KOH in weight with 20% isopropanol in volume) for 30 minutes to form the micro-textured surface with Si pyramids. After being neutralized in concentrated hydrochloric acid, the substrate surface is cleaned by acetone and/or methanol, and native oxide is removed by 10% hydrofluoric acid.

The method 200 includes an act 210 in which a nanowire or other nanostructure array is grown or otherwise formed on the substrate. Each nanowire is formed on the surface of the substrate such that each nanowire extends outward from the surface of the substrate. Each nanowire has a semiconductor composition, as described herein. The nanowire growth may be achieved in an act 212 in which molecular beam epitaxy (MBE) is implemented. The MBE procedure may be implemented under nitrogen-rich conditions. Alternatively or additionally, the substrate may be rotated during the MBE procedure such that each nanostructure is shaped as a cylindrically shaped nanostructure. Each nanowire may thus have a circular cross-sectional shape, as opposed to a plate-shaped or sheet-shaped nanostructure.

In some cases, the MBE procedure may be modified to fabricate the arrangement of layers or segments of each nanowire directed to providing a multi-band structure. Various parameters may be adjusted to achieve the different composition levels of the layers. For instance, the substrate temperature may be adjusted in an act 214. Beam equivalent pressures may be adjusted in an act 216. In some cases, a dopant cell temperature is adjusted to control the doping (e.g., Mg doping) of the nanowires.

In one example, Mg-doped InGaN nanowires were grown by plasma-assisted molecular beam epitaxy (MBE) under N-rich conditions. The growth parameters included a gallium (Ga) beam equivalent pressure of about 7E-8 Torr, a nitrogen flow rate of 1 sccm, and a plasma power of 350 W. The substrate temperature, indium (In) beam equivalent pressure (BEP), and magnesium (Mg) cell temperature were tuned to synthesize different single-band or multi-band InGaN nanowires with various p-doping and alloy concentrations. For instance, for single-band p-GaN nanowires or a GaN layer of a multi-band structure, the substrate temperature was 685° C., and Ga BEP was about 7E-8 Torr. The p-type doping level was tuned by using different Mg cell temperatures. For a p-In_{0.20}Ga_{0.80}N nanowire layer, the substrate temperature was 675° C., the Ga BEP was about 7E-8 Torr, and the In BEP was about 7.3E-8. For p-In_{0.27}Ga_{0.73}N nanowire layers, the substrate temperature was 662° C., the Ga BEP was about 7E-8 Torr, and the In BEP was about 7.3E-8. For p-In_{0.35}Ga_{0.65}N nanowire layers, the substrate temperature was 640° C., the Ga BEP was about 7E-8 Torr, and the In BEP was about 3.5E-8. For quadruple-band InGaN nanowires, the growth conditions are similar to those of the constituting single-band nanowires but with varying thicknesses for each segment. The substrate temperature may refer to a thermocouple reading of a substrate heater, which may be different from the actual substrate surface temperature, which may depend on the sample size, substrate holder, and mounting configuration.

The act 210 may include additional, fewer, or alternative acts. For instance, the act 210 may include one or more acts directed to forming a seed other initial layer in preparation for growth of the nanowires. The seed layer may be configured to promote the nucleation of the nanowires. In some cases, the seed layer is composed of, or otherwise includes, Ga. Further details regarding the use of seed layers are set forth below in connection with a number of examples as well as in the above-referenced patent documents.

As shown in FIG. 2, the method 200 further includes an act 220 in which the array is decorated with a co-catalyst arrangement. Dual catalysts are deposited across the array of nanowire. As described herein, the dual catalysts may be disposed in a core-shell configuration. In some cases, one of the dual catalysts is distributed as nanoparticles, while the other one is configured as a shell around or about the nanoparticles.

The selective deposition of the nanoparticles may be achieved via implementation of two or more deposition procedures. In the example of FIG. 2, the act 220 includes an act 222 in which one or more of the deposition procedures is configured. The configuration may be directed to establishing a ratio of the dual catalysts, which, in turn, establishes a product ratio (e.g., a H₂-to-CO ratio). For instance, the deposition procedure(s) may be configured to establish a gold-to-oxide material ratio by weight that falls within a range from about 1.2:3.7 to about 1:9.5. Further details are provided below in connection with a number of examples.

In the example of FIG. 2, the act 220 include an act 224 in which co-catalyst nanoparticles are deposited on the nanowires. The nanoparticles may be composed of, or otherwise include, gold and/or other metals, as described herein. In some cases, the deposition of the nanoparticles includes implementation of an e-beam evaporation procedure to deposit the nanoparticles in an act 226. Additional or alternative procedures may be used, including, for instance, other physical vapor deposition procedures, such as sputtering, as well as atomic layer deposition procedures. The oxide material catalysts may then be deposited via implementation of a deposition procedure (e.g., photo-deposition or electro-deposition procedure) in an act 228. Further details regarding examples of the e-beam and photo-deposition procedures are set forth hereinbelow and in one or more of the above-referenced U.S. patents.

In one example, an Au—Cr₂O₃ co-catalyst arrangement is deposited on an array of multi-stacked InGaN/GaN nanowires via a combination of e-beam deposition and photo-deposition procedures. The Au nanoparticles are deposited on the surface of the InGaN/GaN nanowires using an e-beam evaporator, e.g., with a deposition rate of 0.01 kÅ/s for 500 sec with prior HCl (hydrochloric acid) dips.

After deposition of the Au nanoparticles, Cr₂O₃ is loaded by a photo-deposition process, which may be performed in a sealed Pyrex chamber with a quartz lid. After placement in the chamber, 60 mL deionized water (purged with Ar for 20 mins before use), HAuCl₄ (≥99.0%, Sigma Aldrich), K₂CrO₄ (≥99.0%, Sigma Aldrich), and 15 mL methanol (99.8%, ACP Chemicals) are added in sequence. The chamber is evacuated and irradiated for 30 min for photo-deposition of the Cr₂O₃.

The method 200 may include one or more additional acts directed to forming the photocatalytic structures of the device. For instance, in some cases, the method 200 includes an act 230 in which the photocatalytic structures of the device are annealed. The parameters of the anneal process may vary.

The order of the above-described acts of the method 200 may differ from the example shown. For instance, the annealing of the act 230 may be implemented before or after the deposition of the nanoparticles in the act 220.

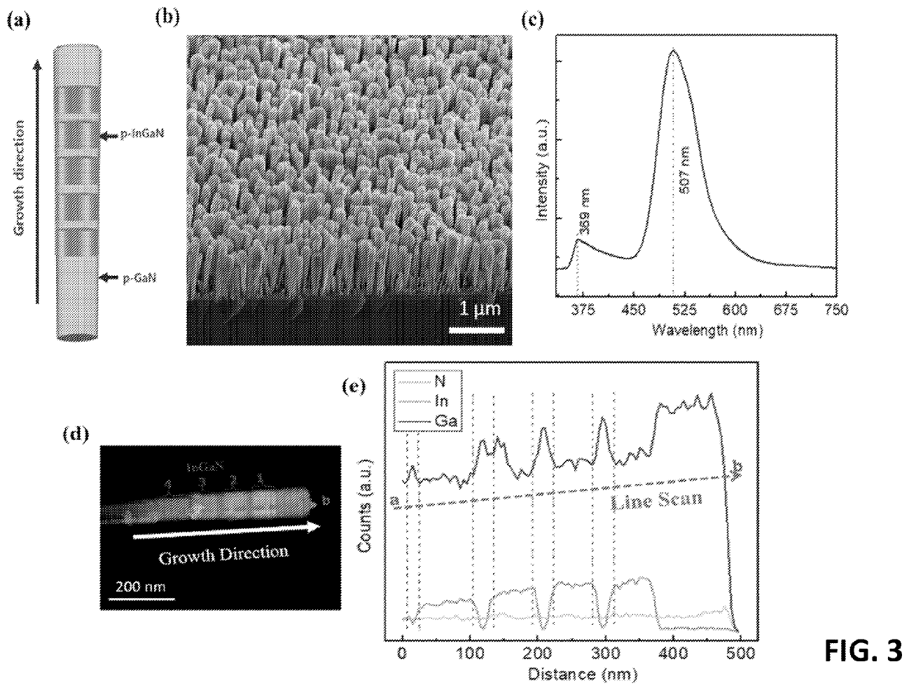

Details regarding examples of the above-described devices, and methods are now provided in connection with FIGS. 3-7. The examples include multi-stacked InGaN/GaN nanowires decorated with a dual core/shell Au—Cr2O₃ cocatalyst arrangement for synthesis of syngas from photocatalytic CO₂ reduction. The examples demonstrate that Au and Cr₂O₃ exhibit unique synergy for activating the inert CO₂ molecule. The linear CO₂ is effectively deformed into a bent state with an O—C—O angle of 116.5°, thus significantly reducing the reaction energy barrier of CO₂ reduction toward CO. The hydrogen evolution reaction is also promoted by the dual cocatalysts. These characteristics combine with the useful properties of the multi-stacked InGaN/GaN nanowires to achieve a distinct activity of 1.08 mol/gcat/h for syngas formation from the sole inputs of CO₂, H₂O, and concentrated solar light. An STS efficiency of 0.89% was obtained. Furthermore, through controlled engineering of the dual Au—Cr₂O₃ cocatalyst arrangement, the H₂/CO ratio was tuned in a broad range from 1.6 to 9.2, opening a wide window for satisfying the input parameters of processes for various downstream products.

### Growth and Fabrication of Example Photocatalytic Devices.

Examples of vertically aligned InGaN/GaN nanowires were grown on a Si substrate by radio frequency plasma-assisted MBE under nitrogen-rich conditions. To achieve efficient harvesting of solar photons, a multi-stacked nanowire structure of GaN (Mg-doped)—InGaN (Mg-doped) segments was grown. Detailed descriptions of the growth procedures can be found in the above-referenced patent publications, as well as in Kibria et al., “Visible light-driven efficient overall water splitting using p-type metal-nitride nanowire arrays,” Nat. Commun. 6, 6797 (2015), the entire disclosure of which is incorporated by reference.

As shown in FIG. 3, several segments of InGaN nanowires, capped with a thin GaN layer, were incorporated to minimize the formation of misfit dislocations, aiming at reducing electron-hole recombination. After in situ oxide desorption at about 935° C., a thin (about 6 nm) Ga seeding layer was deposited to promote the nucleation of nanowires. A forward plasma power of about 350 W with the nitrogen flow rate of 1.2 standard cubic centimeters per minute was employed during the full structure growth. The InGaN/GaN nanowires along the growth direction (c-axis) possess an average length of 600-750 nm and a diameter of 70-90 nm (see, e.g., part b of FIG. 3). The nanowires are spontaneously grown on the substrate with high uniformity. The photoluminescence (PL) spectrum shown in part c of FIG. 3 exhibits a typical optical emission peak at about 507 nm, corresponding to a bandgap of 2.45 eV (In_{0.25}Ga_{0.75}N). The broad emission peak suggests intra-and inter-nanowire indium fluctuations.

Structural properties of the InGaN/GaN nanowires were further analyzed by scanning transmission electron microscopy (STEM) and energy dispersive X-ray spectrometry (EDX). Part d of FIG. 3 shows a high-angle annular dark field (HAADF) image of an InGaN/GaN nanowire, illustrating the atomic number contrast between GaN (darker) and InGaN (brighter) regions. As can be seen, the nanowires have four segments of InGaN (each about 70-80 nm long). Variations of the signals of In Lα, Ga Kα, and N Kα along the nanowire axial direction (non-dashed line in part d of FIG. 3) are plotted in part e of FIG. 3, clearly showing the multi-stacked structure of the InGaN/GaN nanowire. In this case, an outer shell composed of GaN is present along the sidewalls of the InGaN segments, and has a thickness less than about 10-15 nm. The InGaN stacks are numbered 1 to 4 in part c of FIG. 3. The formation of the InGaN/GaN nanostructure is attributed to the enhanced surface desorption of In at the growth temperature and the difference in formation enthalpies between InN and GaN. Herein, the multi-stacked InGaN/GaN nanowires vertically aligned on silicon substrate are highly favorable for photon harvesting and charge carrier generation. Furthermore, the array of nanowires provides an ideal platform with high surface area for loading active sites.

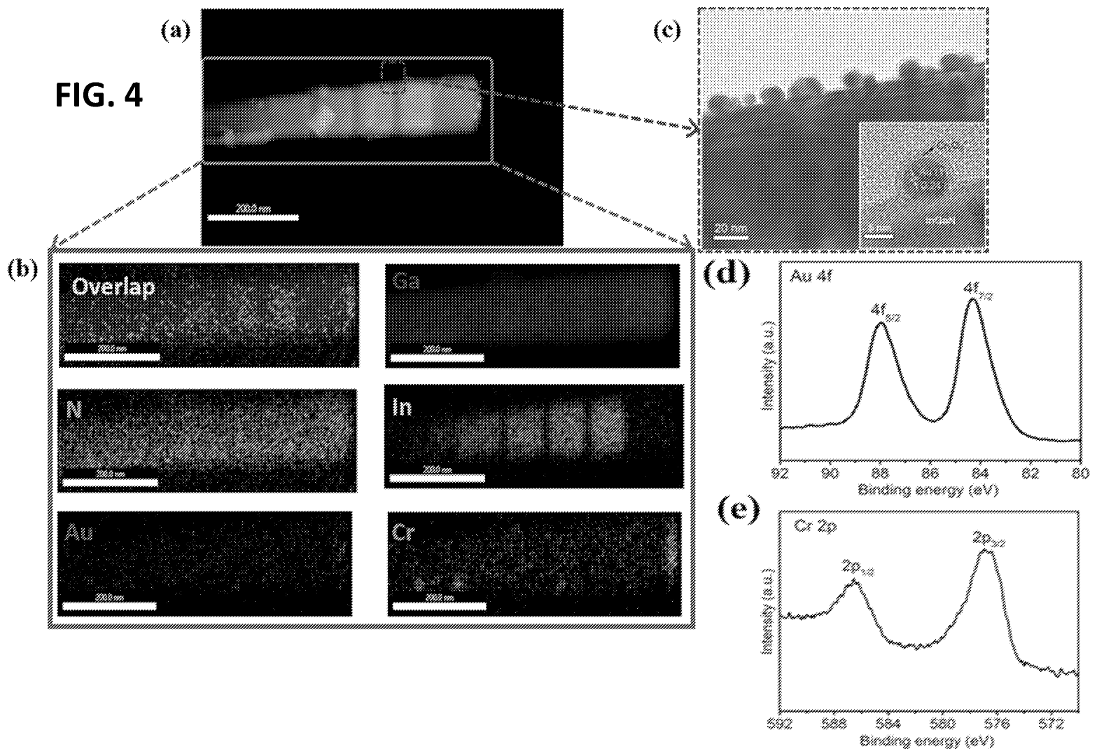

With the use of the multi-stacked InGaN/GaN nanowires as supports, dual Au—Cr₂O₃ cocatalysts with various ratios were deposited in sequential order by employing an e-beam evaporation and photo-deposition process, respectively. A transmission electron microscopy (TEM) image confirmed the core-shell structure of the Au—Cr₂O₃ co-catalysts with a gold core diameter of 5-10 nm and Cr₂O₃ shell thickness of 2-3 nm. The (111) facet of Au and amorphous structure of the Cr₂O₃ shell was further observed by high-resolution TEM characterization as shown in the inset of part c of FIG. 4. The EDX elemental mapping of a single nanowire revealed that Au and Cr₂O₃ were uniformly distributed across the nanowire (see, e.g., part b of FIG. 4), which was confirmed by a relative line scan elemental plot and an EDX curve. The X-ray photoelectron spectroscopy (XPS) measurements of the co-catalyst were conducted accordingly. The typical peaks emerging at binding energies of 84.3 eV (4f_{7/2}) and 88.0 eV (4f_{5/2}) are assigned to metallic Au (see, e.g., part d of FIG. 4), while the featured peaks at binding energies of 576.9 eV (Cr 2p3/2) and 586.6 eV (Cr 2p_{1/2}) correspond to Cr^{III} state from Cr₂O₃ (see, e.g., part e of FIG. 4). The above-mentioned results indicate the successful coupling of the Au—Cr₂O₃ co-catalysts with the multi-stacked InGaN/GaN nanowires.

Carbon-Neutral Synthesis of Syngas from CO₂ and H₂O.

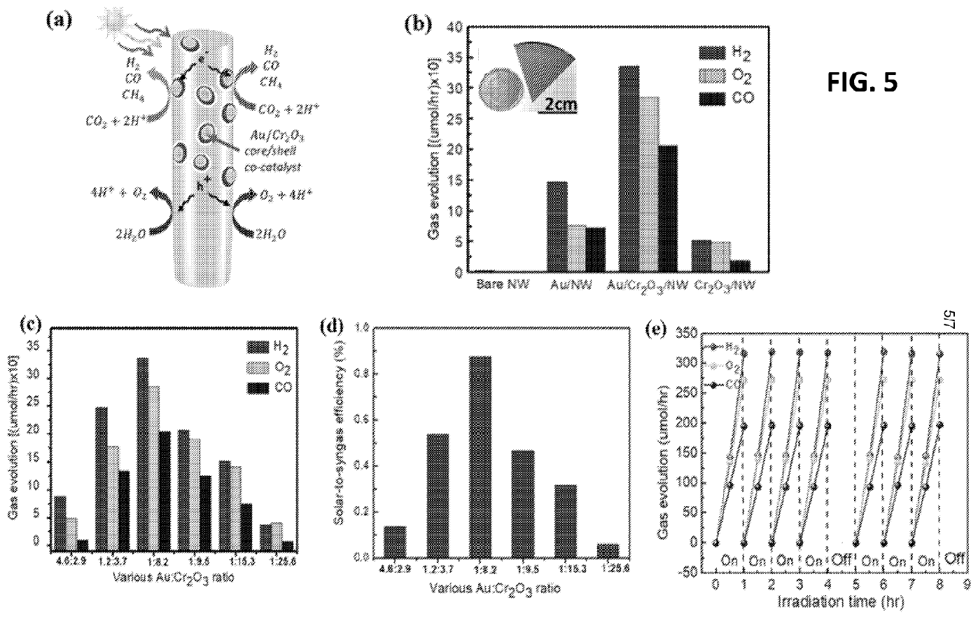

The example Au—Cr₂O₃-decorated InGaN/GaN nanowire-based device was used for photochemical CO₂ reduction in distilled water in a sealed gas-phase reactor. A schematic illustration of one of the nanowires and the reduction reaction is shown in part a of FIG. 5. Upon illumination, the multi-stacked InGaN/GaN nanowires are photoexcited to generate electrons and holes. Water is then split by the photogenerated holes to provide protons. With electrons and protons, CO₂ is hydrogenated toward CO over the Au—Cr₂O₃ co-catalysts, with concomitant formation of H₂. The valence band (VB) and conduction band (CB) energy positions of the photocatalyst device straddle the redox potentials of the CO₂ reduction reaction with H₂O oxidation, thus enabling applied bias-free syngas production.

Upon concentrated sunlight irradiation of 1.6 W·cm⁻², both CO₂ reduction and hydrogen evolution were marginal for bare InGaN/GaN because of the lack of catalytic sites. With the modification of the Au—Cr₂O₃ cocatalyst arrangement, the semiconductor platform demonstrated a dramatic enhancement in syngas activity. To exclude the temperature effect, the reaction chamber was air-cooled at approximately 45-50° C. Under this condition, the thermal effect on the reaction was nearly negligible. Under optimal conditions, a significant syngas generation rate of 1.08 mol/g_{cat}/h was achieved with a favored H₂/CO ratio of 1.6:1 (see part b of FIG. 5), which is a desirable syngas composition for producing methanol and hydrocarbon fuels. Nearly stoichiometric O₂ was yielded simultaneously at a rate of 0.57 mol/g_{cat}/h. No other gaseous carbonaceous products except for a trace amount of CH₄ were detected.

The Au/Cr₂O₃ co-catalyst arrangement was found to significantly outperform the single component of Au and/or Cr₂O₃, suggesting the synergy between Au and Cr₂O₃ in the CO₂ reduction reaction. By varying the Au/Cr₂O₃ ratio, both CO+H₂ activity and the H₂/CO ratio were capable of being tailored at a broad range (see part c of FIG. 5). At an initial Au/Cr₂O₃ ratio of 1/25.6, H₂ and CO were produced at a rate of 0.074 and 0.013 mol/g_{cat}/h, respectively, giving arise to a high H₂/CO ratio of 5.5. The activity of CO/H₂ was improved with increasing Au/Cr₂O₃ ratios. STS efficiency demonstrated a similar trend, peaking at 0.89% when the Au/Cr₂O₃ ratio approached 1:8.2 (see part d of FIG. 5). The peak is likely to arise from the optimal balance between photon harvesting, electron-hole separation, and intrinsic catalytic activity under this situation. Performance was however reduced at higher Au/Cr₂O₃ ratios, and the syngas activity eventually decreased to 0.20 mol/g_{cat}/h at a Au/Cr₂O₃ ratio of 4.6:2.9 with the highest H₂/CO ratio of 9.2. Correspondingly, STS dropped to less than 0.2%. These measurements further validated the cooperative effect between Au and Cr₂O₃ on CO₂ activation and the subsequent conversion, which is consistent with past observations that a metal/oxide interface offers multifunctional sites for stabilizing the key intermediates of CO₂ reduction reaction, thus facilitating the reaction.

In the absence of CO₂, water was stoichiometrically split into H₂ and O₂ over Au—Cr₂O₃-decorated InGaN/GaN nanowires without carbonaceous product formation. This result validated the possibility of utilizing H₂O as the exclusive hydrogen source for the CO₂ reduction reaction without sacrificial agents. An isotopic experiment with the use of ¹³CO₂ as the feedstock was performed to clarify the origin of CO. The signal at m/z=29 that assigned to ¹³CO appeared in the gas chromatography-mass spectrometry analysis, confirming that syngas primarily came from the CO₂ reduction in water. What is more, no products were formed under dark, revealing that concentrated solar light is the driving force of the reaction. Based on the discussions above, it is seen that syngas was indeed produced from solar-powered CO₂ reduction with H₂O via artificial photosynthesis.

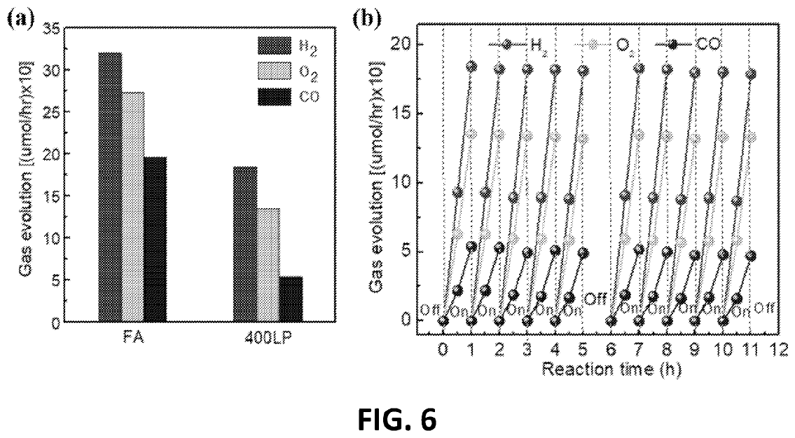

The durability of Au—Cr₂O₃-decorated InGaN/GaN nanowires was also investigated. As shown in part e of FIG. 5, there was no appreciable decay on syngas evolution rate after 4 consecutive runs. What is more, the morphology of the sample as characterized by SEM did not vary notably after the stability test. These observations indicate the superior durability of the photocatalytic device. To confirm the photocatalytic CO₂ reduction activity under visible light illumination (A greater than 400 nm), repeated cycles for the output gas evolution of H₂ and CO from the Au—Cr₂O₃-decorated multi-stacked InGaN/GaN nanowires were observed without notable degradation as well. The evolution rates of H₂ and CO were measured to be 0.368 mol/g_{cat}/h and 0.108 mol/g_{cat}/h, respectively. The calculated STS efficiency is about 0.39% in the visible light, which is relatively lower than that of 0.89% under AM 1.5 G solar light illumination as presented in FIG. 6. This variation was attributed to the multi-stacked InGaN/GaN nanowires only utilizing the light with wavelengths ranging from 400 nm to 507 nm (see part c of FIG. 3) upon visible light illumination, filtering out the wavelengths lower than 400 nm.

The influence of light intensity on the reaction was also investigated. Upon light illumination below 16 suns, both H₂ and CO evolution rate as well as STS efficiency increase considerably with light intensity increments, arising from the increasing abundance of the photoexcited charge. The STS efficiency, however, slightly decreases at higher photon intensity, which is likely to be associated with saturated photon absorption and severe electron-hole recombination.

In preparation for the above-referenced measurements, CO₂ reduction was implemented in an airtight gas circulation system (about 450 mL). The example devices were placed on a polytetrafluoroethylene holder in a Pyrex chamber equipped with a quartz lid. After evacuation, the system was then filled with pure CO₂ until the pressure reached around 55-60 kPa. Then, 2.5 milliliters of distilled water were inserted into the reaction cell. The water was then purged with Ar for 20-30 min prior to illumination. The added water was then vaporized under the illumination of a 300 W Xe lamp.

Density functional theory (DFT) calculations were employed to investigate the role of the Au—Cr₂O₃ co-catalysts in the reaction. Optimized configurations of the models were employed for Au(111), Cr₂O₃(0001) and Au₄/Cr₂O₃ surfaces. An Au₅₅ cluster model was also used to further consider the corner and edge sites of Au nanoparticles. Upon CO₂ adsorption, it is seen that, the interactions between CO₂ and Au(111) or Cr₂O₃(0001) surface are negligible. CO₂ remains nearly linear on the surface, which is similar to its original configuration in the gas phase. In sharp contrast, CO₂ was adsorbed strongly on the Au₄/Cr₂O₃ interface, with the C atom binding to the O atom underneath and two O atoms binding to the adjacent Au and Cr atom with elongated C—O bond lengths of 1.27 Å and 1.29 Å, respectively. The strong interaction drastically deforms the linear geometry of CO₂, with a bent O—C—O angle of 116.50°.

The energetics associated with CO₂ adsorption on different surfaces in terms of the adsorption energy (E_{ad}) were also calculated. Compared to Au(111) and Cr₂O₃(0001), the larger negative E_{ad} value of CO₂ on Au₄/Cr₂O₃ indicates an exothermic process, which is indicative of that CO₂ can be effectively activated at Au₄/Cr₂O₃ interface.

To further investigate the bonding interaction between the adsorbate and catalyst surface, charge transfers between CO₂ and Au₄/Cr₂O₃ were examined by Bader charge analysis. There is a charge transfer from Au₄/Cr₂O₃ to the adsorbed CO₂ with CO₂ gaining 0.151e, in sharp contrast with the inappreciable values of 0.032e and 0.040e in the case of Au(111) and Cr₂O₃(0001). The charge distribution contour of CO₂ adsorption on Au₄/Cr₂O₃ is also observed, where electron charge density redistribution is clearly observed around the interface. It further validates the interaction between CO₂ and Au₄/Cr₂O₃, thus facilitating the subsequent conversion.

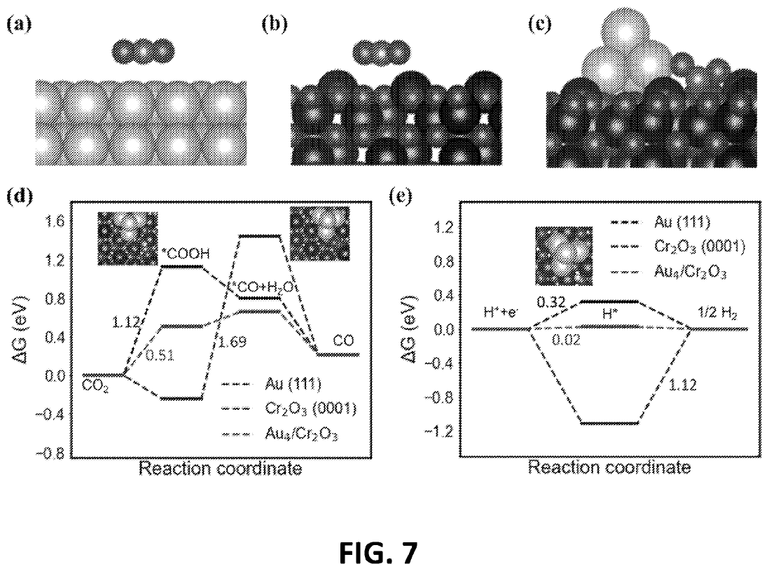

To elucidate the reaction mechanism at the molecular level, DFT calculations were further performed to study the reaction pathways of CO₂ reduction to CO on different substrates, which proceed via the formation of two *COOH and *CO intermediates. Part d of FIG. 7 demonstrates the Gibbs free energy diagram of CO₂ reduction on Au(111), Cr₂O₃(0001) and Au₄/Cr₂O₃, respectively. In the case of Au(111) and Cr₂O₃(0001), it was found that the potential-determining steps, i.e., the formation of *COOH on Au(111) and *CO on Cr₂O₃(0001) , are highly endergonic, leading to high energy barriers of 1.12 eV and 1.69 eV for CO₂RR, respectively. In contrast, Au₄/Cr₂O₃ interface binds *COOH and *CO moderately stronger. The potential-determining step of the CO₂ reduction reaction on Au₄/Cr₂O₃ is the *COOH formation with a small free energy change of 0.51 eV. The lower energy barrier suggests that Au and Cr₂O₃ are cooperative for accelerating the CO₂ reduction reaction toward CO. It is noted that similar results were observed for the hydrogen evolution reaction. As shown in part e of FIG. 7, the Au₄/Cr₂O₃ interface again gives the lowest HER energy barrier compared to Au(111) and Cr₂O₃(0001), exhibiting an impressively low hydrogen adsorption Gibbs free energy Cr₂O₃(0001) , the rational Au₄/Cr₂O₃ dual cocatalyst is beneficial for both the CO₂ reduction and hydrogen evolution reactions, thus facilitating syngas synthesis, which is in good agreement with the experimental observations.

In addition to Au₄/Cr₂O₃, the CO₂ reduction and hydrogen evolution reactions were also investigated at Au₁₀/Cr₂O₃ to include the effect of the Au cluster size for reactions. The results show that the reaction energetics on Au₁₀/Cr₂O₃ are similar to that of Au₄/Cr₂O₃. Additionally, to consider all possible adsorption sites on Au nanoparticles, e.g., the corners and the edges, the reaction energetics on the Au₅₅ cluster model were also investigated. The results show that Au₅₅ is more active for the CO₂ reduction and hydrogen evolution reactions compared to Au(111), but the energy barriers for these reactions are still higher than that of Au₄/Cr₂O₃, further suggesting the synergy between Au and Cr₂O₃ is useful for the superior performance. To understand the side reactions on the catalyst surface, CO₂ dissociation to C on defects of Cr₂O₃ were further investigated. By DFT calculations, it was found that the energy barrier of *C formation is very high (2.17 eV), indicative of a difficult CO₂ dissociation to C on O vacancy of Cr₂O₃.

By coupling a core/shell Au—Cr₂O₃ dual cocatalyst arrangement with multi-stacked InGaN/GaN nanowires, the above-described examples have demonstrated highly efficient syngas synthesis with the sole inputs of CO₂, H₂O, and concentrated solar light illumination. The formation rate of CO+H₂ is as high as 1.08 mol/g_{cat}/h. The combination of Au and Cr₂O₃ is synergistic to bend the linear CO₂ molecule to reduce the energy barrier of CO₂RR, and to promote HER simultaneously, thus serving as a useful contribution to the unprecedented performance. Together with the superior structural and optoelectronic properties of the InGaN/GaN nanowires, a record-high STS efficiency of 0.89% was achieved with broadly tunable H₂/CO ratios by controlled engineering of the Au—Cr₂O₃ co-catalyst arrangement, thereby providing suitable feedstocks for various downstream products. Isotopic testing validated that syngas originated from the CO₂ reduction. Stoichiometric oxygen was concurrently evolved from water splitting. A carbon-neutral route for green syngas production is therefore provided.

Described above are examples of the carbon-neutral synthesis of syngas from CO₂ and H₂O powered by solar energy. The disclosed devices are configured for photochemical reduction of CO₂ with H₂O into syngas using a core/shell Au—Cr₂O₃ dual cocatalyst decorated multi-stacked InGaN/GaN nanowires with sunlight as the only energy input. First-principles DFT calculations revealed that Au and Cr₂O₃ are synergetic in deforming the linear CO2 molecule to a bent state with an O—C—O angle of 116.5°, thus significantly reducing the energy barrier of the CO₂ reduction reaction compared to that over a single component of Au or Cr₂O₃. The hydrogen evolution reaction is promoted by the same cocatalyst simultaneously. By combining the cooperative catalytic properties of the Au—Cr₂O₃ co-catalyst arrangement with the optoelectronic characteristics of the multi-stacked InGaN semiconductor nanowires, the example photocatalyst devices demonstrated high syngas activity of 1.08 mol/g_{cat}/h with widely tunable H₂/CO ratios between 1.6 and 9.2 under concentrated solar light illumination. Nearly stoichiometric oxygen was evolved from water splitting at a rate of 0.57 mol/g_{cat}/h; and isotopic testing confirms that syngas originated from the CO₂ reduction reaction. The solar-to-syngas energy efficiency approached 0.89% during overall CO₂ reduction coupled with water splitting. The examples thus establish a useful solution for carbon-neutral synthesis of syngas with the sole inputs of CO₂, H₂O, and solar light.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A photocatalytic device comprising:
a substrate; and
an array of conductive projections supported by the substrate and extending outward from the substrate, each conductive projection of the array of conductive projections has a semiconductor composition configured for charge carrier generation in response to solar radiation;
wherein each conductive projection of the array of conductive projections is decorated with a co-catalyst arrangement, the co-catalyst arrangement comprising gold and an oxide material.

2. The photocatalytic device of claim 1, wherein the co-catalyst arrangement is disposed in a core-shell configuration with a gold core.

3. The photocatalytic device of claim 1, wherein the co-catalyst arrangement has a gold-to-oxide material ratio by weight that falls within a range from about 1.2:3.7 to about 1:9.5.

4. The photocatalytic device of claim 1, wherein the semiconductor composition comprises a III-nitride semiconductor material.

5. The photocatalytic device of claim 4, wherein the III-nitride semiconductor material is doped with magnesium.

6. The photocatalytic device of claim 4, wherein the III-nitride semiconductor material is InGaN.

7. The photocatalytic device of claim 1, wherein each conductive projection of the array of conductive projections comprises a nanowire.

8. The photocatalytic device of claim 1, wherein the oxide material comprises chromium oxide.

9. The photocatalytic device of claim 1, wherein the co-catalyst arrangement is uniformly distributed across the array of conductive projections.

10. The photocatalytic device of claim 1, wherein:
each conductive projection of the array of conductive projections comprises a layered arrangement of semiconductor materials; and
the layered arrangement of semiconductor materials establishes a multiple band structure.

11. The photocatalytic device of claim 1, wherein the co-catalyst arrangement is configured for catalysis of carbon dioxide (CO₂) reduction.

12. A method of using the photocatalytic device of claim 1, the method comprising:
illuminating the photocatalytic device with incident solar radiation; and
capturing a product of the CO₂ reduction.

13. The method of claim 12, wherein the co-catalyst arrangement is configured such that the product comprises syngas.

14. The method of claim 12, wherein the photocatalytic device is illuminated without application of a bias voltage to the photocatalytic device.

15. The method of claim 12, further comprising:
disposing the photocatalytic device in a container; and
supplying water or water vapor and CO₂ to the container.

16. The method of claim 15, wherein illuminating the photocatalytic device is implemented while the container is free of a sacrificial agent for the CO₂ reduction.

17. A method of fabricating a photocatalytic device, the method comprising:
providing a substrate having a surface;
forming an array of conductive projections on the substrate such that each conductive projection of the array of conductive projections extends outward from the substrate, each conductive projection of the array of conductive projections having a semiconductor composition configured for charge carrier generation in response to solar radiation; and
decorating each conductive projection of the array of conductive projections with a co-catalyst arrangement,
wherein decorating each conductive projection comprises:
depositing gold nanoparticles on each conductive projection; and
after depositing the gold nanoparticles, depositing an oxide material to dispose the co-catalyst arrangement in a core-shell configuration.

18. The method of claim 17, wherein decorating each conductive projection comprises configuring a deposition procedure to establish a gold-to-oxide material ratio by weight that falls within a range from about 1.2:3.7 to about 1:9.5.

19. The method of claim 17, wherein depositing the oxide material comprises implementing a photo-deposition procedure.

20. The method of claim 17, wherein depositing the gold nanoparticles comprises implementing an e-beam evaporation procedure to deposit the gold nanoparticles.

21. The method of claim 17, wherein forming the array of conductive projections comprises implementing a molecular beam epitaxy (MBE) procedure to grow a stack of a plurality of III-nitride semiconductor segments, wherein:
each III-nitride semiconductor segment of the plurality of III-nitride semiconductor segments has a respective bandgap for charge carrier generation in response to solar radiation; and
the stack comprises a plurality of GaN segments, each GaN segment of the plurality of GaN segments being disposed between a respective adjacent pair of III-nitride semiconductor segments of the plurality of III-nitride semiconductor segments.

22. A method of fabricating a photocatalytic device, the method comprising:
providing a substrate;
forming an array of conductive projections on the substrate such that each conductive projection of the array of conductive projections extends outward from the substrate, each conductive projection of the array of conductive projections having a semiconductor composition configured for charge carrier generation in response to solar radiation; and
decorating each conductive projection of the array of conductive projections with a co-catalyst arrangement,
wherein decorating each conductive projection comprises:
depositing metallic nanoparticles on each conductive projection using a vapor deposition procedure; and
after depositing the metallic nanoparticles, implementing a further deposition procedure to deposit an oxide material to form a core-shell configuration of the co-catalyst arrangement.

23. The method of claim 22, wherein the metallic nanoparticles comprise gold.

24. The method of claim 22, wherein:
the vapor deposition procedure comprises e-beam evaporation; and
the further deposition procedure comprises a photo-deposition procedure.

25. A catalytic device comprising:
a substrate; and
a co-catalyst arrangement supported by the substrate, the co-catalyst arrangement comprising a metallic material and an oxide material,
wherein:
the co-catalyst arrangement is disposed in a core-shell configuration;
the metallic material is disposed as a core of the core-shell configuration; and
the oxide material is disposed as a shell about the core.

26. The catalytic device of claim 25, wherein the metallic material is gold.

27. A method of fabricating a catalytic device, the method comprising:
providing a substrate; and
forming a plurality of co-catalyst arrangements supported by the substrate, each co-catalyst arrangement of the plurality of co-catalyst arrangements being disposed in a core-shell configuration;
wherein forming the plurality of co-catalyst arrangements comprises:
implementing a vapor deposition procedure to form a core of the core-shell configuration; and
after implementing the vapor deposition procedure, implementing a further deposition procedure to form a shell of the core-shell configuration.

28. The method of claim 27, wherein the vapor deposition procedure comprises e-beam evaporation.

29. The method of claim 27, wherein the further deposition procedure comprises a photo-deposition procedure.

30. The method of claim 27, wherein the further deposition procedure comprises an electro-deposition procedure.
